(19) United States
(12) Patent Application Publication
(10) Pub. No.: US 2016/0161530 A1
(43) Pub. Date: Jun. 9, 2016

(54) CURRENT SENSING CIRCUIT

(71) Applicants: Hyundai Motor Company, Seoul (KR); Kia Motors Corporation, Seoul (KR)

(72) Inventors: Seong Min Lee, Hwaseong (KR); Jin Myeong Yang, Busan (KR); Youn Sik Lee, Suwan (KR); Je Hwan Lee, Seongnam (KR); Sang Cheol Shin, Suwon (KR); Han Geun Jang, Yongin (KR)

(21) Appl. No.: 14/663,848

(22) Filed: Mar. 20, 2015

(30) Foreign Application Priority Data
Dec. 4, 2014 (KR) 10-2014-0172895

(51) Int. Cl. G01R 15/18

(52) U.S. Cl. CPC G01R 15/18

(57) ABSTRACT

A current sensing circuit includes: a current sensing transformer including a primary coil connected to an input terminal of a converter and a secondary coil; a first current path connected to the secondary coil, including a first resistor, and configured to allow a forward current induced in the secondary coil to flow therethrough; and a second current path connected to the secondary coil, including a second resistor, and configured to allow a reverse current induced in the secondary coil to flow therethrough, wherein the first current path further includes at least one voltage drop element disposed between the secondary coil and the first resistor.

### CROSS REFERENCE TO RELATED APPLICATION

The present application claims priority to and the benefit of Korean Patent Application Number 10-2014-0172895 filed on Dec. 4, 2014, the entire contents of which are incorporated herein for all purposes by reference.

### BACKGROUND

1. Technical Field

The present disclosure generally relates to a current sensing circuit and, more particularly, to a current sensing circuit that can eliminate an offset voltage from the output terminal of the current sensing circuit.

2. Description of the Related Art

In a hybrid or electric vehicle, a low-voltage Direct Current (DC)-DC converter (LDC) supplies power to various types of automotive electronic components used for vehicles. That is, the LDC converts a high voltage output from a high-voltage battery into a low voltage and supplies the lower voltage as power to automotive electronic components.

The transfer of power to the output terminal of the LDC is performed according to the change in the current of the LDC. To change the current, the LDC has a plurality of switching elements. That is, the LDC is intended to change the direction of current to a forward direction and a reverse direction according to the ON-OFF operation of the switching elements, and is generally classified into a full-bridge converter and a half-bridge converter.

Therefore, current sensing performed by an LDC plays an important role in controlling the LDC. The current sensing is performed using a current sensing circuit including a current sensing transformer (CT).

However, when a synchronous rectifier is used in the output rectification stage of the secondary side of the current sensing transformer, a problem arises in that a section in discontinuous current mode is eliminated, and current flows in a reverse direction in the power transfer section of a low-load region in which an output load required by the converter is low. When a reverse current increases, an offset voltage is generated at the output terminal of the current sensing circuit in a 0 A section due to the voltage-second balance condition of the current sensing transformer, so that a higher current is sensed at a low input current.

### SUMMARY

Accordingly, embodiments of the present disclosure have been made keeping in mind the above problems occurring in the related art. An object of the present disclosure is to provide a current sensing circuit that can eliminate an offset voltage from the output terminal of the current sensing circuit.

In order to accomplish the above object, the present disclosure provides a current sensing circuit, including: a current sensing transformer including a primary coil connected to an input terminal of a converter and a secondary coil; a first current path connected to the secondary coil, including a first resistor, and configured to allow a forward current induced in the secondary coil to flow therethrough; and a second current path connected to the secondary coil, including a second resistor, and configured to allow a reverse current induced in the secondary coil to flow therethrough, wherein the first current path further includes at least one voltage drop element disposed between the secondary coil and the first resistor.

The at least one voltage drop element may be at least one of a resistor, a diode, and a Zener diode.

The first resistor may have resistance less than that of the second resistor.

A positive voltage applied to the first resistor and a negative voltage applied to the second resistor may have an equal magnitude.

The at least one voltage drop element may drop a voltage by a magnitude of an offset voltage applied to the first resistor in a low-load region in which an output load required by the converter is less than a preset reference value.

The first current path may further include a first diode, such that the forward current flows through the first current path, and the at least one voltage drop element may be connected in series with the first diode.

A number of and a type of the at least one voltage drop element may depend on a magnitude of an offset voltage applied to the first resistor.

### BRIEF DESCRIPTION OF THE DRAWINGS

The above and other objects, features and advantages of the present disclosure will be more clearly understood from the following detailed description taken in conjunction with the accompanying drawings, in which:

FIGS. 1 and 2 are circuit diagrams showing a current sensing circuit and a converter connected thereto according to embodiments of the present disclosure; and

FIGS. 3A and 3B are diagrams showing graphs indicating a change in a sensed value depending on the magnitude of current before and after connecting to a voltage drop element according to embodiments of the present disclosure.

### DETAILED DESCRIPTION OF THE EMBODIMENTS

Specific structural or functional descriptions related to embodiments according to the present disclosure and disclosed in the present specification or application are merely illustrated to describe embodiments of the present disclosure. The embodiments of the present disclosure may be implemented in various forms and should not be interpreted as being limited to the embodiments described in the present specification or application.

The embodiments according to the present disclosure may be modified in various manners and may have various forms, so that specific embodiments are intended to be illustrated in the drawings and described in detail in the present specification or application. However, it should be understood that those embodiments are not intended to limit the embodiments based on the concept of the present disclosure to specific disclosure forms and they include all changes, equivalents or modifications included in the spirit and scope of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The terms such as “first” and “second” may be used to describe various components, but those components should not be limited by the terms. The terms are merely used to distinguish one component from other components, and a first component may be designated as a second component and a second component may be designated as a first component in the similar manner, without departing from the scope based on the concept of the present disclosure.

Throughout the entire specification, it should be understood that a representation indicating that a first component is “connected” or “coupled” to a second component may include the case where the first component is connected or coupled to the second component with some other component interposed therebetween, as well as the case where the first component is “directly connected” or “directly coupled” to the second component. In contrast, it should be understood that a representation indicating that a first component is “directly connected” or “directly coupled” to a second component means that no component is interposed between the first and second components. Other representations describing relationships among components, that is, “between” and “directly between” or “adjacent to,” and “directly adjacent to,” should be interpreted in similar manners.

The terms used in the present specification are merely used to describe specific embodiments and are not intended to limit the present disclosure. A singular expression includes a plural expression unless a description to the contrary is specifically pointed out in context. In the present specification, it should be understood that the terms such as “include” or “have” are merely intended to indicate that features, numbers, steps, operations, components, parts, or combinations thereof are present, and are not intended to exclude a possibility that one or more other features, numbers, steps, operations, components, parts, or combinations thereof will be present or added.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

Unless differently defined, all terms used here including technical or scientific terms have the same meanings as the terms generally understood by those skilled in the art to which the present disclosure pertains. The terms identical to those defined in generally used dictionaries should be interpreted as having meanings identical to contextual meanings of the related art, and are not interpreted as being ideal or excessively formal meanings unless they are definitely defined in the present specification.

Hereinafter, embodiments of the present disclosure will be described in detail with reference to the attached drawings. The same reference numerals are used throughout the different drawings to designate the same or similar components.

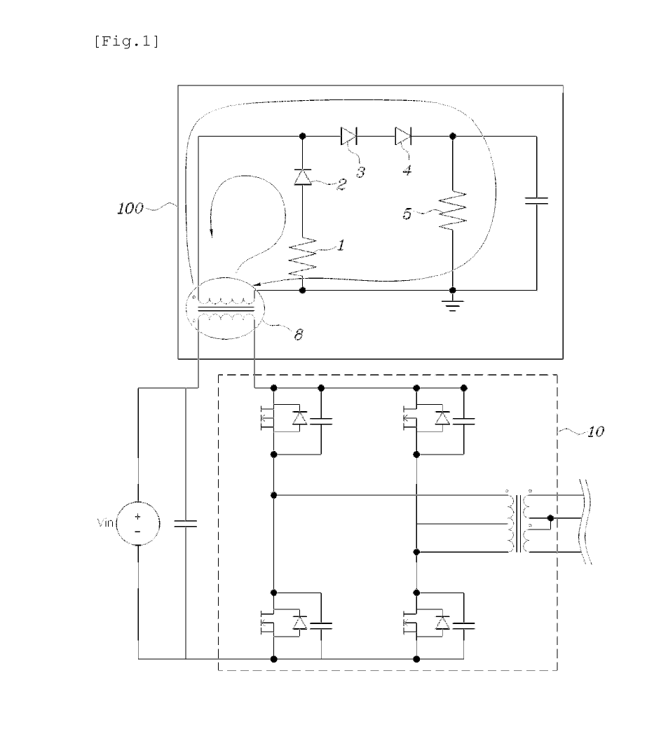

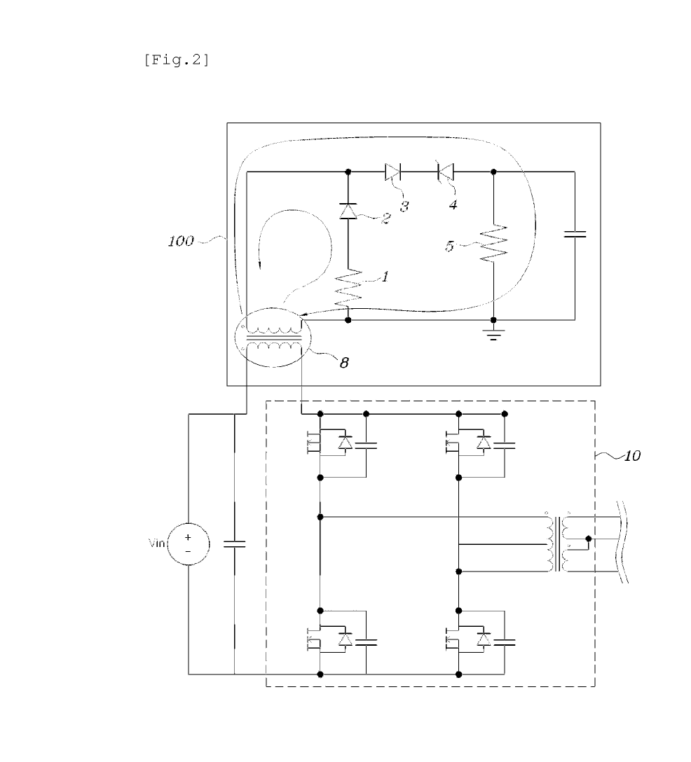

FIGS. 1 and 2 are circuit diagrams showing a current sensing circuit and a converter connected thereto according to embodiments of the present disclosure. A current sensing circuit 100 according to embodiments of the present disclosure includes a current sensing transformer 8 composed of a primary coil connected to the input terminal of a converter 10 and a secondary coil; a first current path connected to the secondary coil and configured to allow a forward current induced in the secondary coil to flow therethrough and to include a first resistor 5; and a second current path connected to the secondary coil and configured to allow a reverse current induced in the secondary coil to flow therethrough and to include a second resistor 1. Here, the first current path may further include at least one voltage drop element 4 disposed between the secondary coil and the first resistor 5. The voltage drop element 4 may be at least one of a resistor, a diode, and a Zener diode. The number of and type of voltage drop elements 4 depend on the magnitude of an offset voltage applied to the first resistor 5. That is, any one of a diode, a resistor, and a Zener diode corresponding to the magnitude of an offset voltage (e.g., a highest possible voltage value) that may be generated in a worst condition may be selected and connected to the first current path.

In the first current path, a first diode 3 is provided such that a forward current may flow, and the voltage drop element 4 is connected in series with the first diode 3. The primary coil of the current sensing transformer 8 is connected to the input terminal of the full-bridge converter 10, and a voltage-second balance condition is maintained due to mutual inductance between the primary coil and the second coil of the current sensing transformer 8.

The current sensing circuit 100 functions to sense current by means of the magnitude of voltage inducted at the first resistor 5. A forward current (i.e., positive current) flows through the first current path, and a reverse current (i.e., negative current) flows through the second current path. Since the reverse current is much less than the forward current, the resistance value of the second resistor 1 is much greater than that of the first resistor 5 so that the voltage-second balance condition may be maintained. That is, when the voltage-second balance condition is satisfied, the magnitudes of a positive voltage applied to the first resistor 5 and a negative voltage applied to the second resistor 1 are equal to each other.

The first current path may be a power transfer path and the second current path may be a backflow path. When a synchronous rectifier is used in the rectification stage of the secondary side of a transformer in the converter 10 or when a gap transformer is used as the transformer, there is a case where a reverse current flows through the first current path in a low-load power transfer section in which the amount of an output load required by the converter 10 is less than a preset reference value. In the case of the gap transformer, an offset voltage may occur due to mutual inductance current.

For example, when the synchronous rectifier is used as the output rectification stage of the converter 10, a Discontinuous Current Mode (DCM) section is eliminated, and current flows in a reverse direction in the power transfer section of a low-load region, thus increasing a current sensing error compared to an existing Continuous Current Mode

(CCM) section. Further, depending on the conditions, an offset voltage is generated in the first resistor 5, so that the magnitude of the current and the magnitude of the sensed voltage may not have a linear relationship.

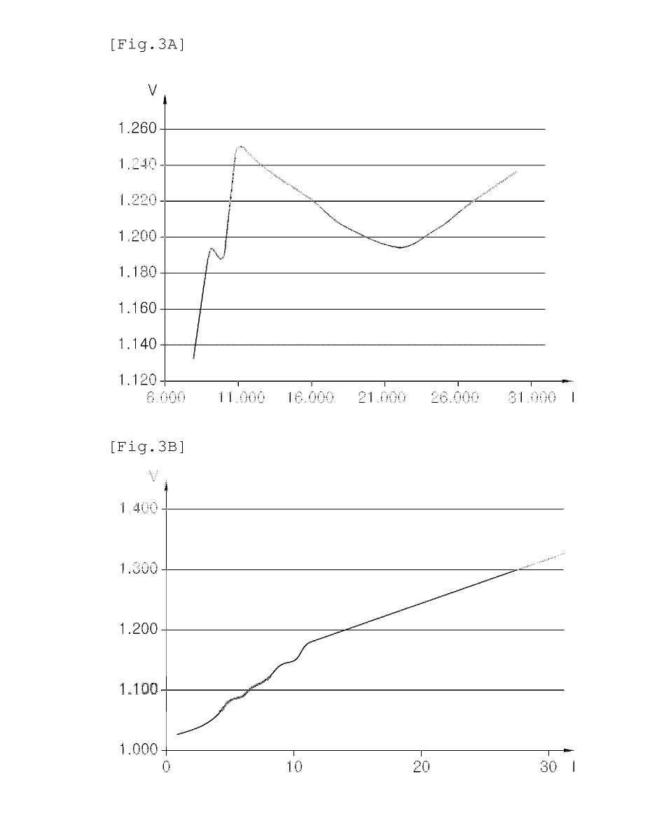

FIGS. 3A and 3B illustrate graphs indicating a change in a sensed value depending on the magnitude of current before and after connecting to the voltage drop element according to embodiments of the present disclosure. Referring to FIGS. 3A and 3B, in a conventional current sensing circuit, a section in which a voltage value does not increase as a current value increases is present, and thus the current and voltage values have a nonlinear relationship. In contrast, in the current sensing current according to embodiments of the present disclosure, it can be seen that current and voltage values have a linear relationship in which the voltage value increases as the current value increases. That is, by overcoming nonlinearity, the current value sensed by the current sensing circuit has a significant meaning.

As a reverse current flows through the first current path, an offset voltage is generated at the first resistor 5. Such an offset voltage may be eliminated by the voltage drop element 4. That is, voltage having the same magnitude as the offset voltage is applied to the voltage drop element 4, thus eliminating the offset voltage.

In the current sensing circuit according to embodiments of the present disclosure, at least one voltage drop element that cannot be implemented using conventional high-speed switching diodes is connected in series to a high-speed switching diode, thus reducing an offset voltage. Further, the disclosed embodiments may drop voltage via a voltage drop element, thus eliminating an output voltage offset. Even further, the disclosed embodiments may solve a problem in which, as current flows in a reverse direction (i.e., negative direction) in a low-load power region, a current sensing error increases, and in which, as an output voltage offset is generated, the nonlinearity of a sensed current value occurs. The disclosed embodiments may also prevent a phenomenon in which a current value higher than an actual current is sensed due to the offset voltage.

Although embodiments of the present disclosure have been disclosed for illustrative purposes, those skilled in the art will appreciate that various modifications, additions and substitutions are possible, without departing from the scope and spirit of the disclosure as disclosed in the accompanying claims. Therefore, the technical scope of the present disclosure should be defined by the technical spirit and scope of the accompanying claims.

What is claimed is:

1. A current sensing circuit, comprising:
a current sensing transformer including a primary coil connected to an input terminal of a converter and a secondary coil;
a first current path connected to the secondary coil, including a first resistor, and configured to allow a forward current induced in the secondary coil to flow therethrough; and
a second current path connected to the secondary coil, including a second resistor, and configured to allow a reverse current induced in the secondary coil to flow therethrough,
wherein the first current path further includes at least one voltage drop element disposed between the secondary coil and the first resistor.

2. The current sensing circuit of claim 1, wherein the at least one voltage drop element is at least one of a resistor, a diode, and a Zener diode.

3. The current sensing circuit of claim 1, wherein the first resistor has resistance less than that of the second resistor.

4. The current sensing circuit of claim 1, wherein a positive voltage applied to the first resistor and a negative voltage applied to the second resistor have an equal magnitude.

5. The current sensing circuit of claim 1, wherein the at least one voltage drop element drops a voltage by a magnitude of an offset voltage applied to the first resistor in a low-load region in which an output load required by the converter is less than a preset reference value.

6. The current sensing circuit of claim 1, wherein:
the first current path further includes a first diode, such that the forward current flows through the first current path, and
the at least one voltage drop element is connected in series with the first diode.

7. The current sensing circuit of claim 1, wherein a number of and a type of the at least one voltage drop element depend on a magnitude of an offset voltage applied to the first resistor.
